(19) United States
(12) Patent Application Publication
(10) Pub. No.: US 2008/0061379 A1
(43) Pub. Date: Mar. 13, 2008

(54) MOS devices with graded spacers and graded source/drain regions

(76) Inventors: Hao-Yu Chen, Kaohsiung City (TW); Shui-Ming Cheng, Chu-bai City (TW); Ken-Ichi Goto, Hsin-Chu City (TW)

Correspondence Address: SLATER & MATSIL, L.L.P., 17950 PRESTON ROAD, SUITE 1000, DALLAS, TX, 75252, US

(21) Appl. No.: 11/518,046

(22) Filed: Sep. 8, 2006

(51) Int. Cl. H01L 29/772

(52) U.S. Cl. 257/382; 257/408

(57) ABSTRACT

An MOS device includes a gate stack overlying a semiconductor substrate and a graded source/drain region adjacent to the gate stack. The graded source/drain region includes a first grade having a first depth, a second grade spaced further apart from a channel region than the first grade, and a third grade spaced further apart from the channel region than the second grade. The depth of the second grade is between the respective depths of the first and the third grades. The MOS device further includes a silicide region on a top surface of the source/drain region wherein the silicide region has an inner edge substantially aligned with an inner edge of the third grade, and a graded gate spacer comprising an inner portion on a sidewall of the gate stack and an outer portion on a sidewall of the inner portion.

### TECHNICAL FIELD

This invention is related generally to semiconductor devices, and more particularly to the structure and manufacturing methods of metal-oxide-semiconductor devices with graded source/drain regions.

### BACKGROUND

Deep-submicron scaling required for VLSI systems dominates design considerations in the microelectronics industry. As the gate electrode length is scaled down, source and drain junctions must be scaled down accordingly to suppress the so-called short channel effects (SCE) that degrade the performance of miniaturized devices. A major problem related to complementary metal-oxide-semiconductor (CMOS) scaling is the undesirable increase in parasitic resistance. As the source/drain junction depth and polycrystalline silicon line width are scaled down into the deep-submicron range, parasitic series resistances of the source/drain diffusion layers and polysilicon gate electrodes increase. A conventional approach to counteract the increase in parasitic series resistances of the source/drain diffusion layers and the polysilicon gate electrodes involves salicide technology, which comprises forming a layer of metal silicide on the source/drain regions and the gate electrode.

Conventional salicide technology for reducing parasitic series resistance has been proven problematic, particularly as design rules plunge into the deep-submicron range, i.e., about 0.18 microns and smaller. For example, as the device dimensions are reduced to achieve higher packing densities and improved performance, the junction depth needs to be scaled in proportion to the junction length. However, the formation of silicide consumes crystalline silicon from the underlying semiconductor substrate. When the junction depth is comparable to the thickness of the silicide, the depth variation of the silicide caused by process variations may cause significant changes in MOS characteristics.

Another significant problem is leakage current. FIG. 1 illustrates a conventional MOS device. The source/drain region includes lightly doped source/drain (LDD) regions 104 and deep source/drain regions 106. Silicide regions 102 typically consume portions of the deep source/drain regions 106, thus lowering the top surfaces of the deep source/drain regions 106. As a result, silicide regions 102 become closer to the respective corner points 108, which are located at interfaces of the LDD regions 104 and the respective deep source/drain regions 106. When the MOS device is scaled down, the distance S decreases, and leakage currents between the silicide region 102 and substrate 100, as symbolized by arrow 110, increase. With continued scaling of the MOS devices, the distance S will continue to decrease and will cause a continued increase in the leakage currents. If processes are not well controlled, silicide regions 102 may become very close to, or even reach, the respective corner points 108, causing a significant leakage current.

Accordingly, there exists a need for a methodology for forming silicide regions in MOS devices having increased reliability and reduced junction leakages.

### SUMMARY OF THE INVENTION

In accordance with one aspect of the present invention, an MOS device includes a gate stack overlying a semiconductor substrate and a graded source/drain region adjacent to the gate stack. The graded source/drain region includes a first grade having a first depth, a second grade spaced further apart from a channel region than the first grade, and a third grade spaced further apart from the channel region than the second grade. The depth of the second grade is between the respective depths of the first and the third grades. The MOS device further includes a silicide region on a top surface of the source/drain region wherein the silicide region has an inner edge substantially aligned with an inner edge of the third grade, and a graded gate spacer including an inner portion on a sidewall of the gate stack, and an outer portion on a sidewall of the inner portion.

In accordance with another aspect of the present invention, an MOS device includes a substrate, a gate stack overlying the substrate, a lightly doped drain/source (LDD) region substantially aligned with a sidewall of the gate stack, a gate spacer on the sidewall of the gate stack, a source/drain extension region in the substrate wherein the source/drain extension region is substantially aligned with an outer edge of the gate spacer, an extension spacer on a sidewall of the gate spacer, a deep source/drain region substantially aligned with an outer edge of the extension spacer, and a silicide region on and substantially aligned with the outer edge of the extension spacer.

In accordance with another aspect of the present invention, a semiconductor device includes a semiconductor substrate, a gate stack on the semiconductor substrate, a graded spacer on a sidewall of the gate stack and includes a first portion and a second portion, wherein the first portion is on the sidewall of the gate stack and the second portion is on a sidewall of the first portion. The second portion has a height less than a third of a height of the first portion. The semiconductor device further includes a source/drain region in the semiconductor substrate. The source/drain region includes three grades, wherein the grades of the source/drain regions further away from the channel region have greater depths than the grades of the source/drain regions close to the channel region.

In accordance with yet another aspect of the present invention, a method for forming an MOS device includes providing a semiconductor substrate, forming a gate stack overlying the semiconductor substrate, forming a graded source/drain region, and forming a graded gate spacer. The step of forming the graded source/drain region includes forming a first grade having a first depth, forming a second grade spaced further apart from a channel region than the first grade wherein the second grade has a second depth greater than the first depth, and forming a third grade spaced further apart from the channel region than the second grade wherein the third grade has a third depth greater than the second depth. The step of forming the graded gate spacer includes forming an inner portion on a sidewall of the gate stack and forming an outer portion on a sidewall of the inner portion. The method further includes forming a silicide region on a top surface of the source/drain region.

In accordance with yet another aspect of the present invention, a method for forming an MOS device includes providing a substrate, forming a gate stack overlying the substrate, implanting a lightly doped drain/source region, forming a gate spacer on a sidewall of the gate stack, implanting a source/drain extension region in the substrate after the step of forming the gate spacer, forming an extension spacer on a sidewall of the gate spacer, implanting a deep source/drain region after the step of forming the extension spacer, and forming a silicide region after the step of implanting the deep source/drain region.

The advantageous features of the present invention include reduced leakage current and improved device drive current.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional MOS device having source/drain silicide regions;

FIGS. 2 through 8 are cross-sectional views of intermediate stages in the manufacture of an MOS device embodiment; and

FIG. 9 illustrates a leakage current distribution of sample devices.

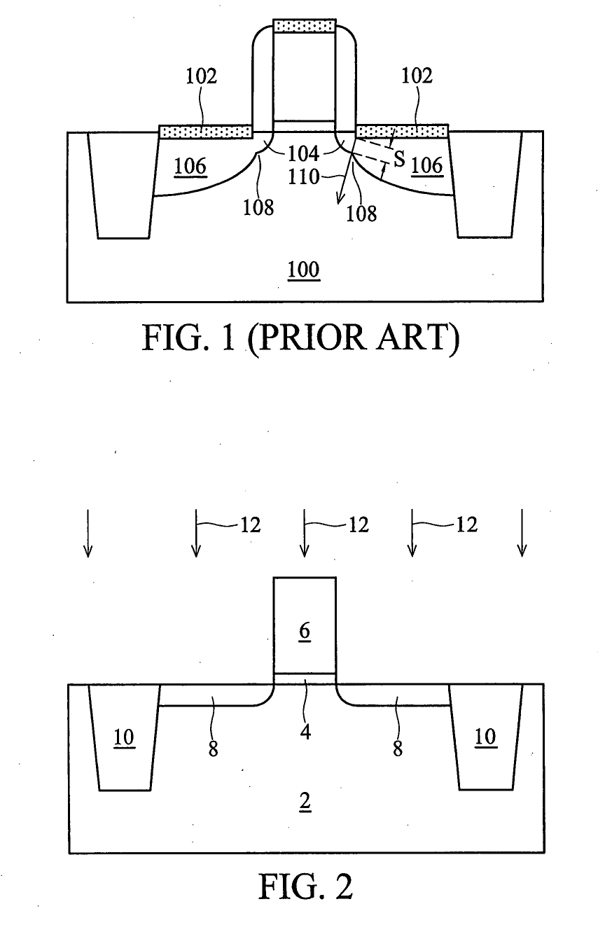

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method of forming MOS devices is discussed in subsequent paragraphs. The intermediate stages for manufacturing preferred embodiments of the present invention are illustrated. Throughout the various views and illustrative embodiments of the present invention, like reference numbers are used to designate like elements.

FIG. 2 illustrates the formation of shallow trench isolation (STI) regions 10 and a gate structure on a surface of a substrate 2. In a preferred embodiment, substrate 2 is a silicon substrate. In other embodiments, substrate 2 comprises SiGe. In yet other embodiments, substrate 2 may include bulk semiconductor, strained semiconductor, compound semiconductor, multi-layer semiconductor, silicon-on-insulator (SOI), strained silicon-on-insulator (SSOI), strained silicon germanium-on-insulator (S—SiGeOI), silicon germanium-on-insulator (SiGeOI), and the like. Preferably, STI regions 10 are formed by etching shallow trenches in substrate 2 and filling the trenches with an insulator such as silicon oxide.

A gate dielectric 4 is formed on the surface of substrate 2. Gate dielectric 4 is preferably formed of oxide. The forming method can be any of the known methods, such as local oxidation of silicon (LOCOS), chemical vapor deposition (CVD), etc. Silicon nitride can also be used since it is an effective barrier for impurity diffusion. The silicon nitride film is preferably formed by thermal nitridation of silicon. It can also be prepared by plasma anodic nitridation using nitrogen-hydrogen or thermal nitridation of SiO₂. Gate dielectric 4 may also be formed of oxynitride, oxygen-containing dielectrics, nitrogen-containing dielectrics, high-k materials, and combinations thereof.

A gate electrode 6 is formed on the gate dielectric 4. In a preferred embodiment, gate electrode 6 is formed of polysilicon. The possible formation methods include, but are not limited to, chemical vapor deposition (CVD), plasma enhanced chemical vapor deposition (PECVD), atomic layer deposition (ALD), and other commonly known methods. In other embodiments, gate electrode 6 includes amorphous silicon, elemental metals, alloys of elemental metals, suicides or nitrides of elemental metals, and combinations thereof. Preferably, gate dielectric 4 and gate electrode 6 are formed by depositing a gate dielectric layer followed by a gate electrode layer, and patterning the gate dielectric layer and the gate electrode layer.

FIG. 2 also illustrates the formation of lightly doped drain/source (LDD) regions 8. As is known in the art, LDD regions 8 are formed by implanting appropriate types of impurities into substrate 2, as symbolized by arrows 12. LDD regions 8 are thus substantially aligned with the respective edges of gate electrode 6.

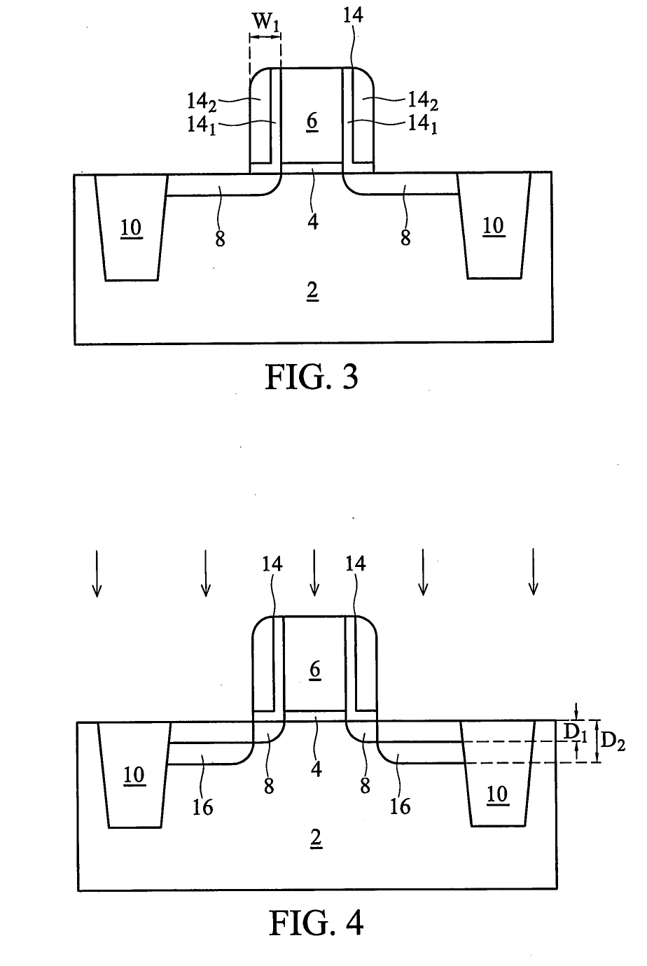

FIG. 3 illustrates the formation of spacers 14. A pair of spacers 14 is formed on sidewalls of the gate dielectric 4 and gate electrode 6. As is known in the art, spacers 14 are preferably formed by blanket depositing a dielectric layer(s), and then anisotropically etching to remove the dielectric material from horizontal surfaces, thereby leaving spacers 14. In a preferred embodiment, spacers 14 include a nitride layer 14₂ on an oxide liner 14₁. Nitride layer 14₂ preferably includes silicon nitride, oxide-rich nitride, and the like, and oxide liner 14₁ preferably includes tetra-ethyl-ortho-silicate (TEOS), silicon oxide, and the like. The thickness W₁ of the spacers 14 is preferably between about 70 Å and about 250 Å, and more preferably about 200 Å. It should be appreciated, however, that the dimensions of the preferred embodiment are related to the scale of the integrated circuit, and the values provided should not limit the scope of the present invention.

Extended source/drain regions 16 are then implanted, as illustrated in FIG. 4. With gate electrode 6 and gate spacers 14 acting as masks, extended source/drain regions 16 are substantially aligned with the edges of the spacers 14. The depth D₂ of the extended source/drain regions 16 is preferably greater than the depth D₁ of the LDD regions 8. More preferably, depth D₂ is between about 40 percent and about 60 percent of depth D₁. Even more preferably, depth D₂ is equal to about two times the depth of depth D₁. In a preferred embodiment, the impurity concentration of the extended source/drain regions 16 is preferably between the impurity concentrations of LDD regions 8 and the subsequently formed deep source/drain regions, and more preferably substantially close to (or even equal to) the impurity concentration of the LDD regions 8.

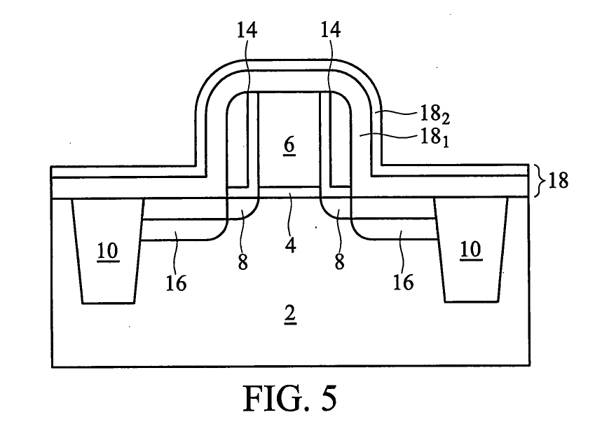

FIG. 5 illustrates the formation of a dielectric layer 18, which includes a first sub layer 18₁ and a second sub layer 18₂. In a preferred embodiment, the first sub layer 18₁ is an oxide layer, which can be formed of silicon oxide, TEOS, and the like. The thickness of the oxide layer 18₁ is preferably between about 40 Å and about 200 Å, and more preferably between about 40 Å and about 80 Å. The second sub layer 18₂, on the other hand, is preferably a nitride layer comprising silicon nitride, oxynitride, hydrogen-rich nitride, hydrogen-less nitride, and the like.

In alternative embodiments, sub layers 18₁ and 18₂ can be formed of other dielectric materials including silicon carbides, silicon oxynitrides, oxides, nitrides, and other applicable dielectric materials. Preferably, but not necessarily, the etching characteristics of sub layers 18₁ and 18₂ are different from that of the spacers 14₂.

In yet other embodiments, dielectric layer 18 comprises a single dielectric layer. Similarly, dielectric layer 18 preferably, but not necessarily, has different etching characteristics from spacers 14₂. In an exemplary embodiment, dielectric layer 18 comprises silicon oxide.

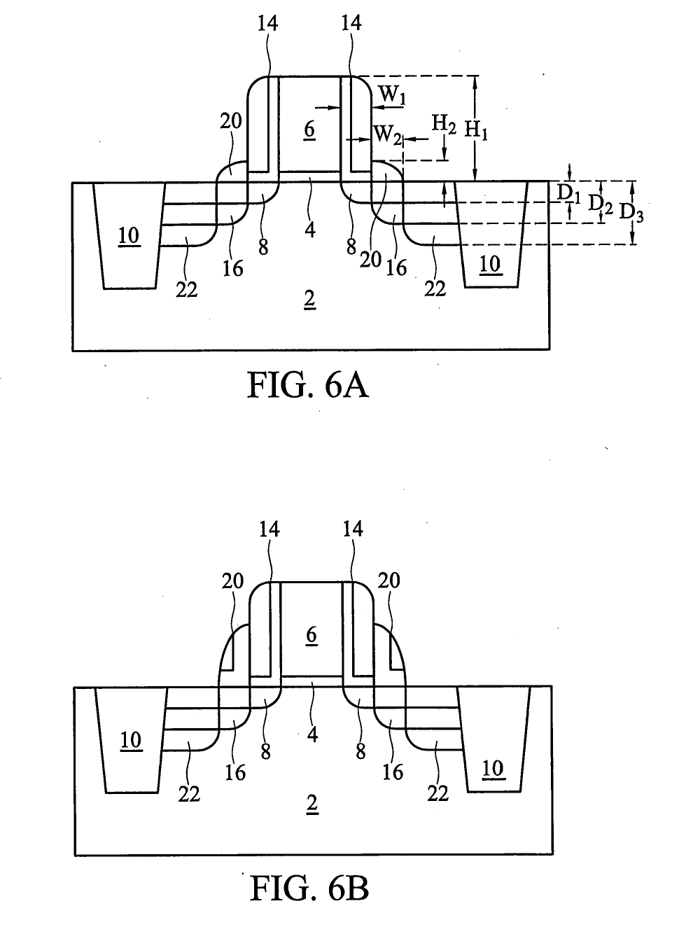

Next, as is shown in FIGS. 6A and 6B, dielectric layer 18 is etched. In an exemplary embodiment, anisotropic dry etching is performed for etching sub layer 18₂, and an end-point is detected to determine whether the underlying layer 18₁ has been reached. In one embodiment, sub layer 18₂ is totally removed. In another embodiment, a portion of the sub layer 18₂ at the corner of its horizontal leg and its vertical leg is left un-removed intentionally by adjusting the time for etching after end-point detection. The underlying layer 18₁ is then etched, for example, by using time-mode isotropic etching, such as wet etching. A portion of the sub layer 18₁ at the corner of its horizontal leg and its vertical leg will remain. The remaining portions of the dielectric layer 18 form extension spacers 20. Extension spacers 20 may include only a portion of sub layer 18₁, as is illustrated in FIG. 6A, or a portion of sub layer 18₁ plus a portion of sub layer 18₂, as is illustrated in FIG. 6B. Preferably, extension spacers 20 have a width W₂ of between about 30 Å and about 100 Å. A ratio of width W₂ to width W₁ is preferably less than about 3, and more preferably between about 1.5 and about 2. A ratio of height H₂ of the extension spacers 20 to a height H₁ of the gate spacers 14 is preferably less than about ⅓, and more preferably between about ⅕ and about ⅛.

In an alternative embodiment wherein dielectric layer 18 comprises a single layer, the end-point mode is used to substantially remove dielectric layer 18. When it is determined that spacer 14₂ has been reached, the etching stops, and extension spacers 20 are formed. If layer 18 consists of a single layer, the exposure of silicon can be used as a signal for stopping the etch process. Preferably, a slight over-etch of silicon is preferred since a recessed source/drain helps enhance the strain applied by the subsequently formed contact etch stop layer. If layer 18 consists of a single layer, oxide can be adopted due to the high etch selectivity between silicon and oxide.

FIGS. 6A and 6B also illustrate the formation of deep source/drain regions 22 after the formation of extension spacers 20. Due to the masking by the extension spacers 20 and spacers 14, the deep source/drain regions 22 are substantially aligned with the respective edges of the extension spacers 20. It should be realized, however, that the subsequent annealing, for example, the annealing for activating source/drain regions, will cause the LDD regions 8, extended source/drain regions 16, and deep source/drain regions 22 to be diffused in the direction of the channel region of the resulting MOS device. These regions are still considered to be substantially aligned to the respective edges of the overlying gate features.

LDD regions 8, extension source/drain regions 16 and deep source/drain regions 22 form graded source/drain regions. Preferably, depth D₂ of the extended source/drain regions 16 is between depth D₁ of LDD regions 8 and depth D₃ of deep source/drain regions 22.

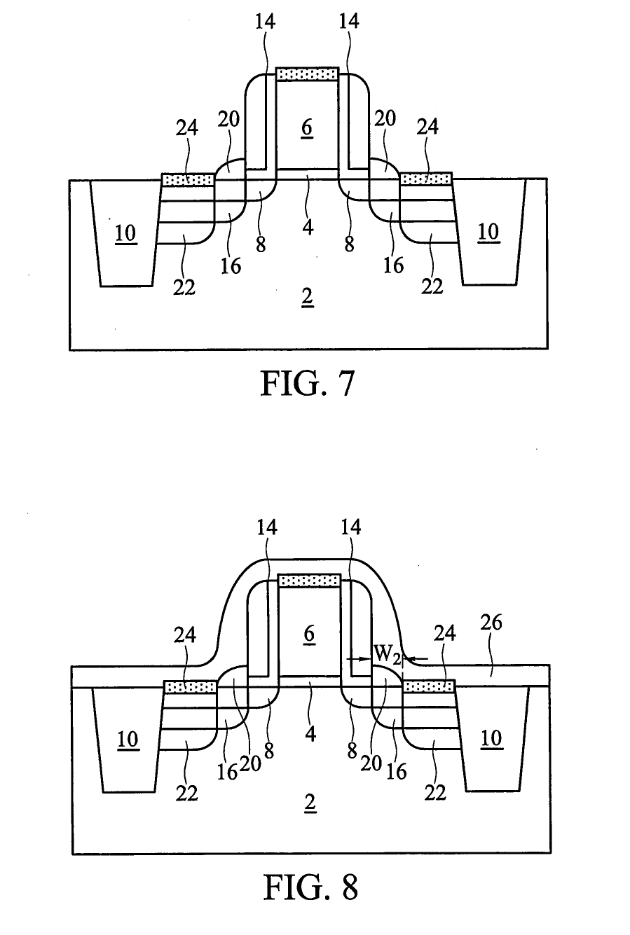

Silicide regions 24 are then formed, as is shown in FIG. 7. Preferably, silicide regions 24 are formed by blanket forming a metal layer, for example, nickel, cobalt, erbium, and combinations thereof, and performing a thermal annealing to cause silicidation between the metal layer and the underlying silicon or silicon germanium-containing substrate. No silicide is formed between the metal layer and the dielectric layer such as spacers 14. Un-reacted metal is then removed. Silicide regions 24 may encroach under the extension spacers 20. However, the width W₂ of the extension spacers 20 is preferably great enough so that the encroached portions of silicide regions 24 do not reach the interface of spacers 14 and extension spacers 20.

One skilled in the art will realize that the preferred embodiments of the present invention can be used to form both NMOS devices and PMOS devices, with the impurity types of LDD regions 8, extended regions 16 and deep source/drain regions 22 being of N-type for NMOS devices and of P-type for PMOS devices.

FIG. 8 illustrates the formation of a contact etch stop layer (CESL) 26. CESL 26 is preferably formed of dielectric materials, such as silicon nitride, silicon carbide, silicon oxynitride, combinations thereof, and/or multi-layers thereof. As is known in the art, besides the function of stopping the etching of the subsequently formed inter-layer dielectric, CESL 26 also provides stress to the channel region of the MOS device.

In FIG. 8, it is observed that by forming extension spacers 20, the silicide regions 24 are shifted away from the channel region by a distance W₂, which is the width of extension spacers 20. The distances between the silicide regions 24 and the nearest junction border are thus increased. As a result, the current crowding effects are reduced and the device drive current is improved. Experimental results have indicated that the drive currents of the preferred embodiment have about a five percent and about eight percent improvement over MOS devices having no extension spacers formed.

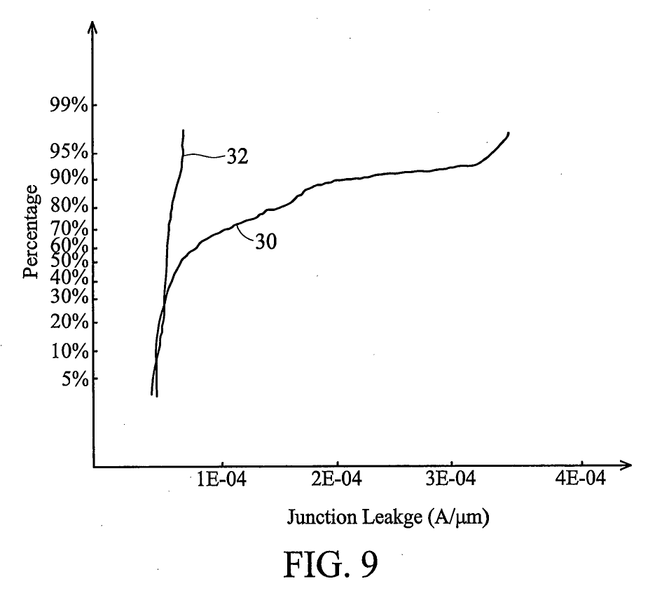

Additionally, the leakage current flowing between silicide regions 24 and substrate 2 is reduced due to the increased distance between the silicide regions and the respective junction borders. FIG. 9 illustrates leakage current distribution of sample devices. The leakage currents of conventional MOS devices (line 30), which have spacers 14 only, and MOS devices having spacers 14 and extension spacers 20 (line 32), are compared. It is observed that the conventional devices have a significantly greater probability of having higher leakage currents, for example, greater than about 1 E-04 A/um, while for MOS devices formed using the preferred embodiment of the present invention, the leakage currents are significantly smaller.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Aspects of the invention include:

1. A method for forming an MOS device, the method comprising:

providing a semiconductor substrate;

forming a gate stack overlying the semiconductor substrate;

forming a graded source/drain region in the semiconductor substrate comprising:
forming a first grade having a first depth:
forming a second grade spaced further apart from a channel region than the first grade, the second grade having a second depth greater than the first depth; and
forming a third grade spaced further apart from the channel region than the second grade, the third grade having a third depth greater than the second depth;

forming a graded gate spacer comprising:
forming an inner portion on a sidewall of the gate stack; and
forming an outer portion on a sidewall of the inner portion; and

forming a silicide region on a top surface of the graded source/drain region.

2. The method of claim 1, wherein the step of forming the outer portion of the graded gate spacer comprises blanket forming a dielectric layer after the step of forming the inner portion, and etching the dielectric layer to leave the outer portion.

3. The method of claim 2, wherein the dielectric layer comprises a nitride on an oxide, and wherein the step of etching comprises a dry etching followed by a wet etching.

4. The method of claim 1, wherein the step of forming the second grade of the graded source/drain region is performed after the step of forming the inner portion of the graded gate spacer and before the step of forming the outer portion of the graded gate spacer, and wherein the step of forming the third grade of the graded source/drain region is performed after the step of forming the outer portion of the graded gate spacer.

5. A method for forming an MOS device, the method comprising:

providing a substrate;

forming a gate stack overlying the substrate;

implanting a lightly doped drain/source region;

forming a gate spacer on a sidewall of the gate stack;

implanting a source/drain extension region in the substrate after the step of forming the gate spacer;

forming an extension spacer on a sidewall of the gate spacer;

implanting a deep source/drain region after the step of forming the extension spacer; and

forming a silicide region after the step of implanting the deep source/drain region.

6. The method of claim 5, wherein the gate spacer comprises a nitride on an oxide.

7. The method of claim 6, wherein the step of forming the extension spacer comprises blanket forming a silicon nitride layer on a silicon oxide layer, and etching the silicon nitride layer and the silicon oxide layer.

8. The method of claim 5, wherein the gate spacer is formed of a single layer.

9. The method of claim 8, wherein the single layer is a nitride layer.

What is claimed is:

1. A metal-oxide-semiconductor (MOS) device comprising:
a semiconductor substrate;
a gate stack overlying the semiconductor substrate;
a graded source/drain region adjacent to the gate stack, wherein the graded source/drain region comprises:
a first grade having a first depth;
a second grade spaced further apart from a channel region than the first grade, the second grade having a second depth greater than the first depth; and
a third grade spaced further apart from the channel region than the second grade, the third grade having a third depth greater than the second depth;
a silicide region on a top surface of the graded source/drain region, the silicide region having an inner edge substantially aligned with an inner edge of the third grade; and
a graded gate spacer comprising an inner portion on a sidewall of the gate stack and an outer portion on a sidewall of the inner portion.

2. The MOS device of claim 1, wherein the outer portion has a height substantially smaller than a height of the inner portion.

3. The MOS device of claim 1, wherein the first grade of the graded source/drain region is substantially aligned with the sidewall of the gate stack, the second grade of the graded source/drain region is substantially aligned with the sidewall of the inner portion of the graded gate spacer, and the third grade of the graded source/drain region is substantially aligned with an outer edge of the outer portion of the graded gate spacer.

4. The MOS device of claim 1, wherein the second grade of the graded source/drain region has an impurity concentration less than an impurity concentration of the third grade of the graded source/drain region.

5. The MOS device of claim 4, wherein the second grade of the graded source/drain region has an impurity concentration substantially close to an impurity concentration of the first grade of the graded source/drain region.

6. The MOS device of claim 4, wherein the second grade of the graded source/drain region has a depth greater than about 50 percent of a depth of the first grade of the graded source/drain region.

7. The MOS device of claim 1, wherein the outer portion of the graded gate spacer has a height of less than about ⅓ of a height of the inner portion of the graded gate spacer.

8. The MOS device of claim 1, wherein the outer portion of the graded gate spacer has a width of greater than about 20 percent of a width of the inner portion of the graded gate spacer.

9. An MOS device comprising:
a substrate;
a gate stack overlying the substrate;
a lightly doped drain/source (LDD) region substantially aligned with a sidewall of the gate stack;
a gate spacer on the sidewall of the gate stack;
a source/drain extension region in the substrate, the source/drain extension region being substantially aligned with an outer edge of the gate spacer;
an extension spacer on a sidewall of the gate spacer, wherein the extension spacer has a bottom surface on the substrate;
a deep source/drain region substantially aligned with an outer edge of the extension spacer; and
a silicide region on and substantially aligned with the outer edge of the extension spacer.

10. The MOS device of claim 9, wherein the extension spacer has a width substantially close to a width of the gate spacer.

11. The MOS device of claim 9, wherein the extension spacer comprises silicon nitride.

12. The MOS device of claim 9, wherein the extension spacer comprises silicon oxide.

13. The MOS device of claim 9, wherein the extension spacer comprises a silicon nitride on a horizontal leg of a silicon oxide liner.

14. The MOS device of claim 9, wherein the source/drain extension region has a depth between a depth of the LDD region and a depth of the deep source/drain region.

15. The MOS device of claim 9, wherein the source/drain extension region has an impurity concentration between an impurity concentration of the LDD region and an impurity concentration of the deep source/drain region.

16. A semiconductor device comprising:
a semiconductor substrate;
a gate stack on the semiconductor substrate;
a graded spacer on a sidewall of the gate stack comprising a first portion and a second portion, wherein the first portion is on the sidewall of the gate stack and the second portion is on a sidewall of the first portion, and wherein the second portion has a height less than a third of a height of the first portion; and
a graded source/drain region comprising three grades in the semiconductor substrate, wherein the graded source/drain region comprises three grades, and wherein the grades of the graded source/drain regions further away from the channel region have greater depths than the grades of the graded source/drain regions closer to a channel region.

17. The semiconductor device of claim 16, wherein the first portion and the second portion of the graded spacer each comprises a nitride on an oxide.

18. The semiconductor device of claim 16, wherein the second portion has a height less than a fifth of a height of the first portion.

19. The semiconductor device of claim 16, wherein the grades of the source/drain regions further away from the channel region have higher impurity concentrations than the grades of the source/drain regions close to the channel region.

20. The semiconductor device of claim 16, wherein a width of the second portion to a width of the first portion is between about 1.5 and about 2.
